(19) United States
(12) Patent Application Publication
(10) Pub. No.: US 2025/0160214 A1
(43) Pub. Date: May 15, 2025

(54) METHOD OF MANUFACTURING THERMOELECTRIC GENERATORS

(71) Applicant: STMicroelectronics International N.V., Geneva (CH)

(72) Inventors: Antonio BELLIZZI, Cologno Monzese (IT); Fabrizio CREVENNA, Olgiate Molgora (IT)

(73) Assignee: STMicroelectronics International N.V., Geneva (CH)

(21) Appl. No.: 18/943,113

(22) Filed: Nov. 11, 2024

(30) Foreign Application Priority Data
Nov. 14, 2023 (IT) 102023000024078

(51) Int. Cl. H10N 10/01

(52) U.S. Cl. CPC H10N 10/01

(57) ABSTRACT

A thermoelectric unit includes a thermoelectric membrane having a first surface at a cavity in a layer of first thermally conductive material. The thermoelectric membrane has a second surface opposite to the first surface with second thermally conductive material arranged in contact with the second surface of the thermoelectric membrane. The thermoelectric membrane includes thermally sensitive material configured to generate via the Seebeck effect a thermoelectric signal indicative of the temperature difference between the second thermally conductive material and the first thermally conductive material. An insulating molding compound is molded onto the second thermally conductive material arranged in contact with the second surface of the thermoelectric membrane wherein mechanical stress develops in the thermoelectric membrane in response to molding. An encapsulation is provided at the second surface of the thermoelectric membrane. The encapsulation counters mechanical stress developed in the thermoelectric membrane in response to the molding of insulating molding compound.

### PRIORITY CLAIM

This application claims the priority benefit of Italian Application for U.S. Pat. No. 10,202,3000024078 filed on Nov. 14, 2023, the content of which is hereby incorporated by reference in its entirety to the maximum extent allowable by law.

### TECHNICAL FIELD

The description relates to manufacturing thermoelectric generator devices.

Solutions as described herein can be applied to thermoelectric generator devices operating on the basis of the Seebeck effect.

### BACKGROUND

Thermoelectric generator devices based on the Seebeck effect are capable of generating an electrical current when a temperature difference is applied to the device. The Seebeck effect is the electromotive force (emf) that develops between two points (in a doped semiconductor, for instance) in response to a temperature difference between these points.

These devices comprise a plurality of basic/unit cells connected in parallel and/or series in order to collect the electrical current generated by each unit cell in the device.

A unit cell of a thermoelectric generator may comprise two differently doped (n+ and p+), electrically coupled resistors that are “embedded” in a structured membrane. Such a structured membrane represents the active portion of the device capable of generating an electrical current when a temperature difference is applied at the two surfaces of the membrane.

In order to apply a temperature difference at the two surfaces of the membrane, the membrane is arranged on a base layer (providing a backside, “cool” side, for instance) and a thermally conductive pad is provided on the opposite surface of the membrane (providing a top/front, “hot” side, for instance).

In various devices, the base layer is arranged on a dissipation frame and the thermally conductive pad is thermally coupled to a heat source via a thermally conductive path, and comprises portions of thermally conductive material and thermally insulating cavities formed as empty regions in the backside layer.

Processing of these devices involves providing an insulating protective package to the devices via transfer molding. Such a molding step involves applying a relatively strong pressure/mechanical stress to the device.

In particular, the active structured membrane may break in response to the molding pressure in its most fragile part, namely the portion of the membrane just above the cavity in the base layer.

Breaking of the structured membrane, that results in failure and rejection of the device, has proven to be a major issue in manufacturing processes of such thermoelectric generator devices.

There is a need in the art for solutions addressing the issues discussed in the foregoing.

### SUMMARY

An embodiment herein comprises a method for an encapsulation process.

Solutions as described herein aim at reducing the mechanical stress applied to the device during molding steps, countering breaking of the structured membrane.

In solutions as described herein, a protective encapsulation/package is provided via a multi-step encapsulation process in order to counter breaking of the structured membrane, for instance at its most fragile portion.

In solutions as described herein, a first encapsulation step comprises providing a protective layer on the front surface of the structured membrane.

In solutions as described herein, the protective layer may be provided by laminating a mold film or by dispensing/spin coating insulating material in order to apply a relatively low pressure that does not cause the structured membrane to break.

### BRIEF DESCRIPTION OF THE DRAWINGS

One or more embodiments will now be described, by way of example only, with reference to the annexed figures, wherein:

FIG. 1 is a cross-sectional view illustrative of the structure of a thermoelectric generator device;

FIG. 2 is illustrative of issues that may arise when processing a thermoelectric generator device according to a conventional approach; and

FIGS. 3A to 3H are cross-sectional views illustrative of a sequence of processing steps according to embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

Thermoelectric generator devices based on the Seebeck effect are devices capable of converting a temperature difference into an electrical current.

Such devices may comprise a plurality of basic/unit cells that are electrically connected in parallel and/or series in order to collect current contributions generated by every single unit cell.

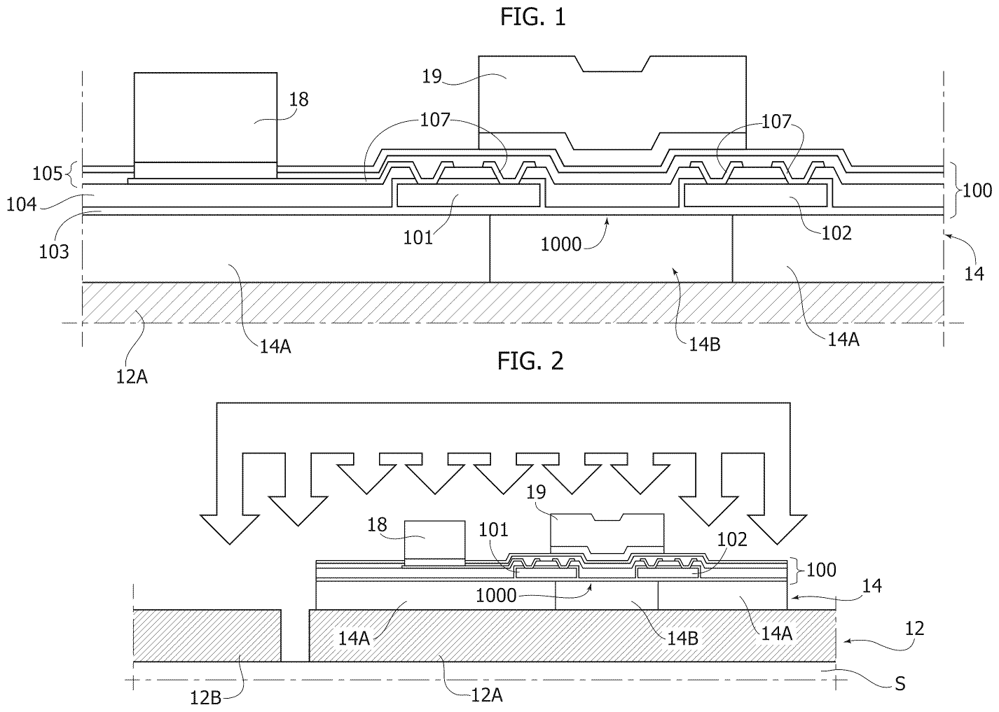

FIG. 1 is illustrative of the structure of a unit cell of such a thermoelectric generator device.

As illustrated, the structure of a unit cell in FIG. 1 may comprise: a structured (multilayer) membrane 100; a backside supporting layer 14 supporting the structured membrane 100, comprising thermally conductive portions (referenced with the references 14A in FIG. 1) and thermally insulating “empty” portions or cavities 14B; and electrically and thermally conductive pads 18 and 19 provided on the top surface of the structured membrane 100.

The structured membrane 100 as considered herein may comprise, for instance: a thermal oxide layer 103 having a thickness, for instance, of 1.5 microns; a borophosphosilicate glass (BPSG) layer 104 having a thickness, for instance, of 600 nm; two differently doped resistors (of poly-Si, for instance), such as an n+ doped resistor 101 and a p+ doped resistor 102, “embedded” in the BPSG layer 104; electrically conductive routing traces 107 (of metal such as Al and Cu, for instance) providing the desired electrical couplings to the resistors 101 and 102 respectively; and passivation layers 105, possibly comprising a TEOS layer of 500 nm and a SiON layer of about 500 nm.

Processing to obtain an assembly as exemplified in FIG. 1 may comprise: providing a supporting layer 14 of thermally conductive material; forming a structured membrane (as exemplified in FIG. 1) at a surface of the supporting layer 14; forming a cavity 14B in the supporting layer 14 at the region of the structured membrane 100 indicated with the reference 1000 in the figure.

Processing to obtain such a thermoelectric unit cell is conventional in the art, which makes it unnecessary to provide a more detailed description herein.

In the following, the structure of the membrane 100 will not be further detailed in the description and the related figures, being otherwise understood that the details of the structured membrane 100 presented are merely exemplary in so far as embodiments of the present description may advantageously be applied to membranes having a different structure.

As illustrated in FIG. 1, the backside supporting layer 14 having the structured (thermoelectric) membrane 100 formed thereon (that is, the unit cell) is arranged on a mounting location 12A of a substrate/frame.

A frame 12 as discussed herein may have a plurality of unit cells arranged at respective mounting locations 12A of the frame 12.

The frame also comprises a connection frame portion (visible in FIG. 2 and referenced therein with the reference 12B) that is configured to electrically couple (in parallel and/or series) the plurality of unit cells in the device. This facilitates collecting the electrical current generated by each individual unit cell.

As mentioned, the unit cell is capable of generating an electrical current in response to a temperature difference applied to its two surfaces.

In more detail: the bottom/back side is the “cold” side of the unit cell and it is in contact with the (thermally conductive) backside supporting layer 14 arranged on the (thermally conductive) substrate/frame 12 (dissipation frame), and the top/front side is the “hot” side of the unit cell; a (thermally conductive) pad 19 is formed on the front/top surface of the structured membrane 100 that is configured to provide a landing point for a thermally conductive path coupling the pad 19 (and thus the front/top surface of the membrane 100) to a heat source.

Another (electrically conductive) pad 18 is also provided on the top surface of the membrane 100 to provide a landing point to an electrically conductive path from the unit cell to the connection frame 12B, for collecting the current generated by the unit cell.

In some embodiments, the pads 18 and 19 may be made of a same material that is both thermally and electrically conductive (a metal such as copper, for instance).

FIG. 2 is illustrative of a processing step where an insulating molding compound (an epoxy resin, for instance) is molded onto the unit cells arranged on a substrate/frame 12.

During such a molding step, a relatively high pressure (indicated by the arrows in FIG. 2) is applied to the molding compound and transferred to the unit cell and, in particular, to the structured membrane 100.

Mechanical stress due to pressure applied may damage the devices during processing, causing failure (and consequently, rejection) of the device.

Specifically, it is observed that the structured membrane 100 is more likely to break at the portion 1000 over the empty portion or cavity 14B of the backside supporting layer 14.

Solutions as described herein aim at reducing the mechanical stress applied to the structured thermoelectric membrane 100 during molding steps, thus countering breaking of the portion of the structured membrane above the empty portion 14B.

In solutions as described herein, a protective encapsulation/package is provided via a multi-step encapsulation process.

In solutions as described herein, a first encapsulation step comprises providing a protective layer on the front/top surface of the structured membrane.

In solutions as described herein, the protective layer may be provided by laminating a mold film or by dispensing/spin coating electrically insulating material in order to apply a relatively low pressure that does not cause the structured membrane to break.

In solutions as described herein, the protective layer may advantageously be provided at wafer/panel level, thus resulting in a more efficient assembly flow.

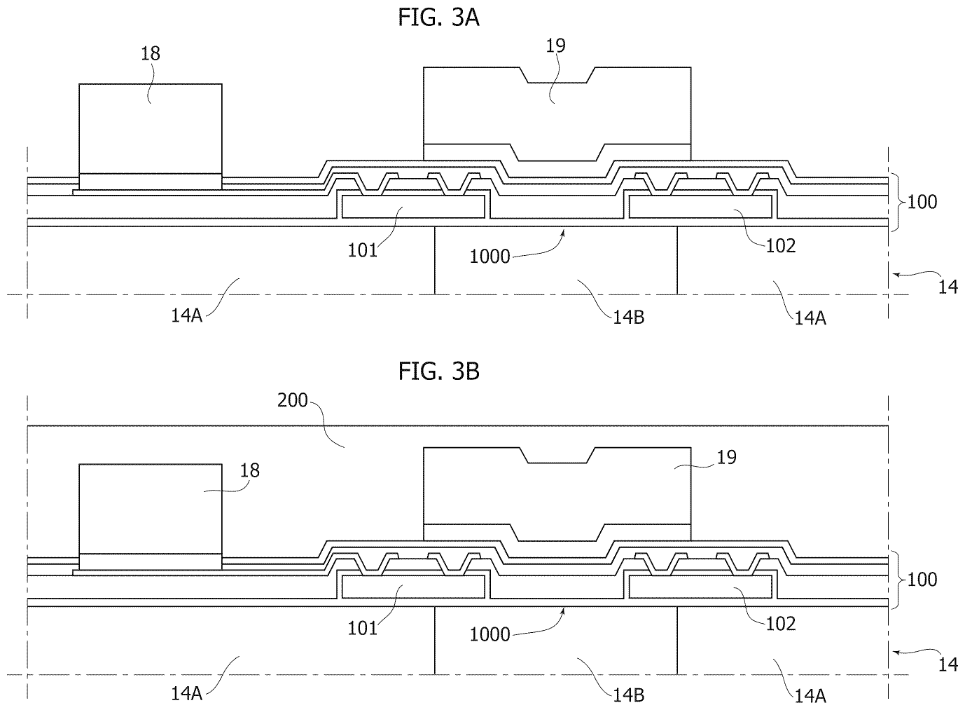

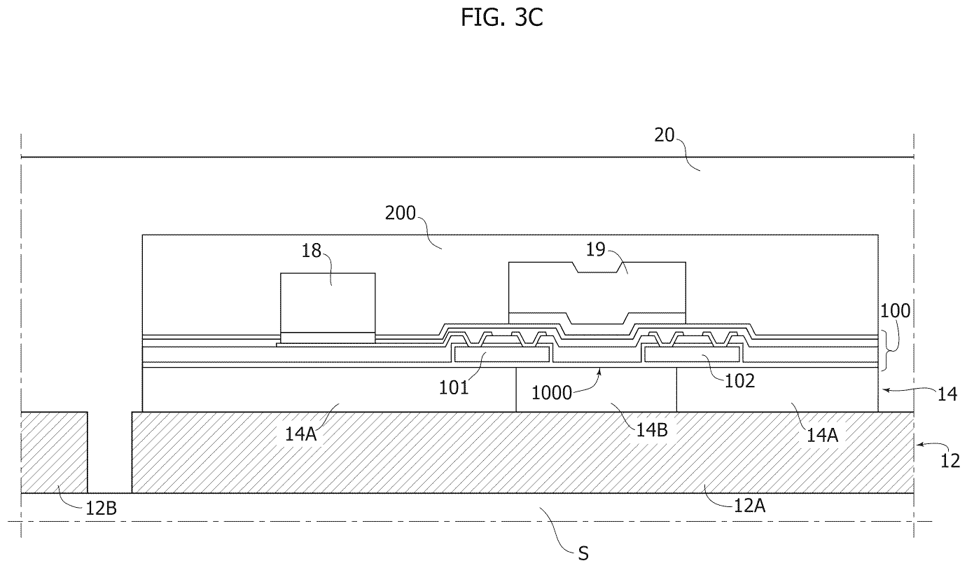

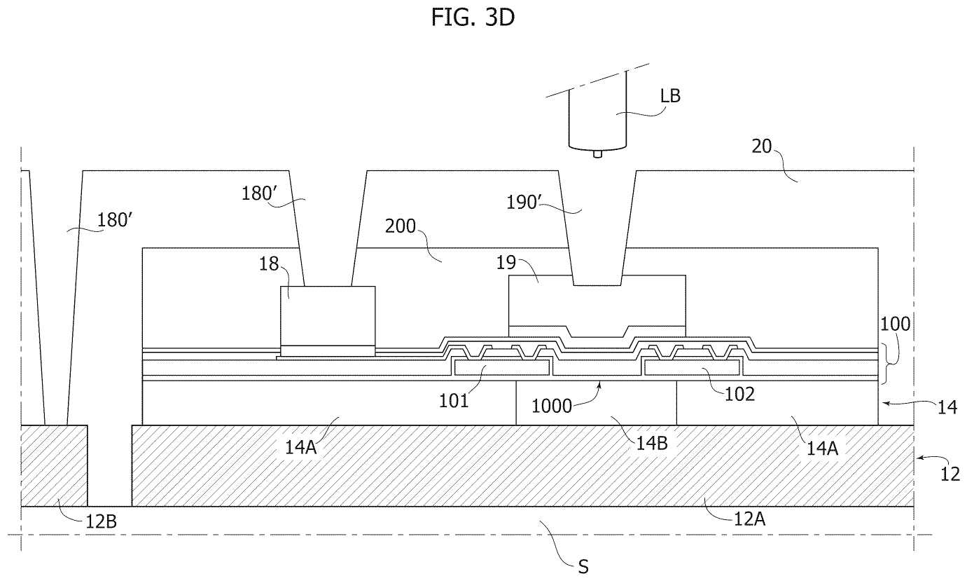

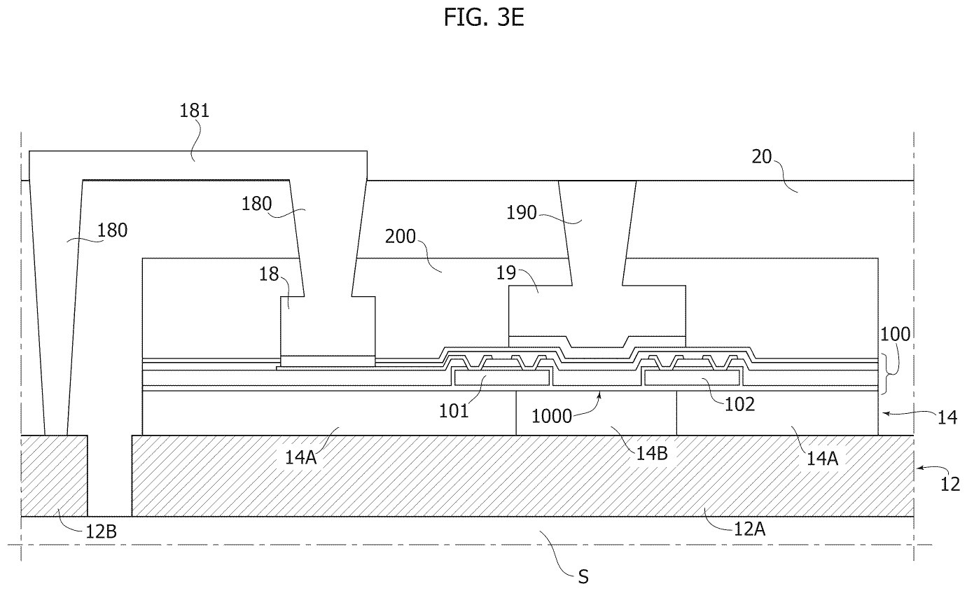

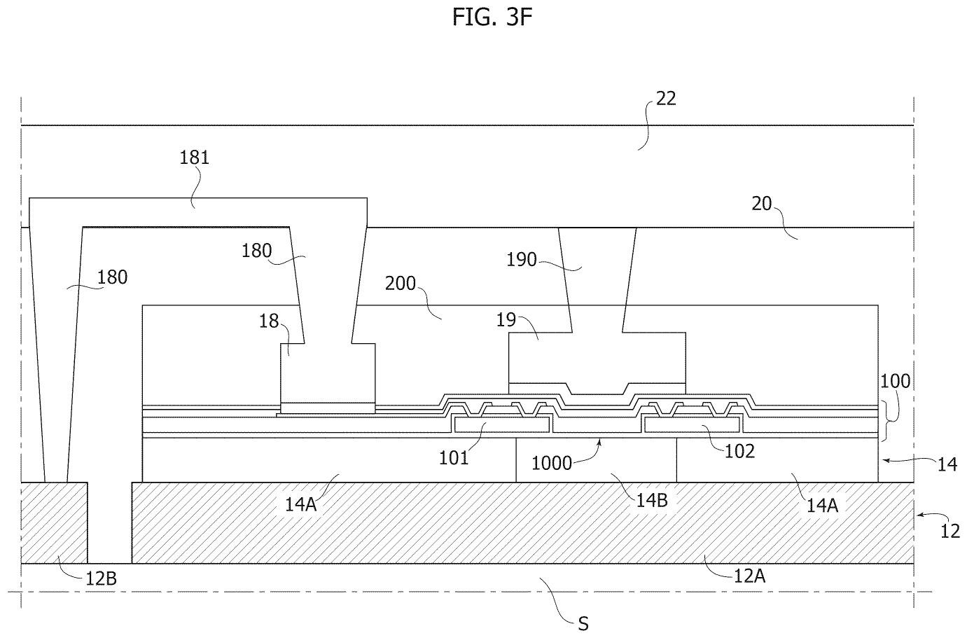

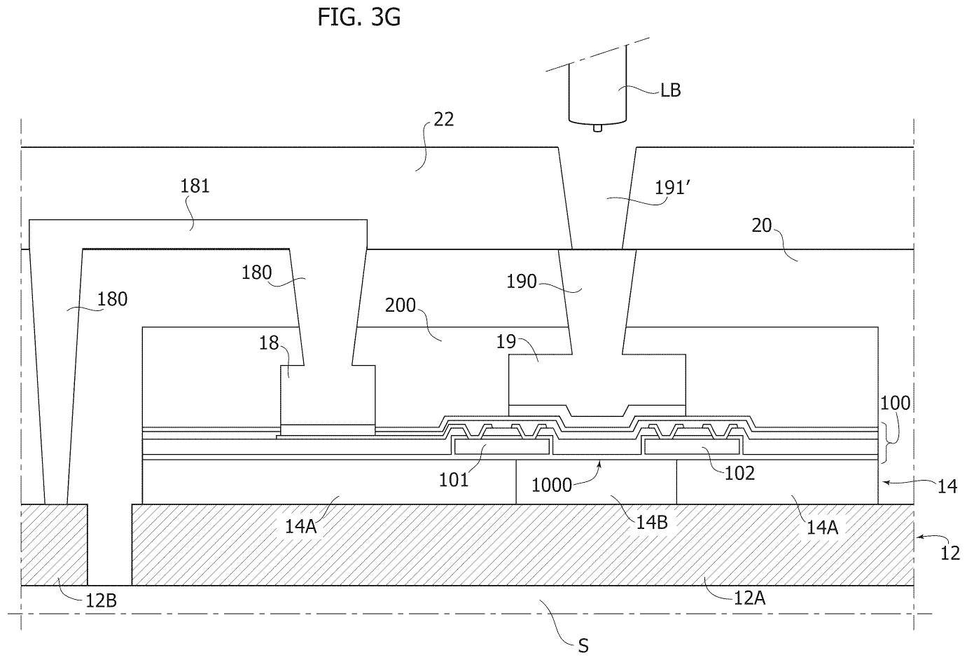

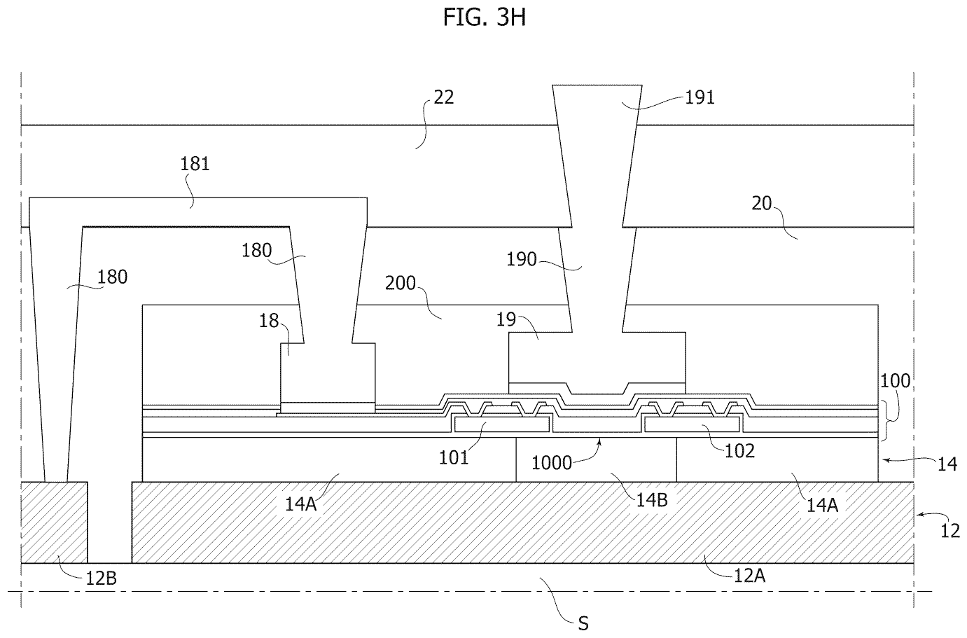

FIGS. 3A to 3H illustrates a sequence of processing steps according to embodiments of the present description.

It will be otherwise appreciated that the sequence of steps of FIGS. 3A to 3H is merely exemplary insofar as: one or more steps illustrated in FIGS. 3A to 3H can be omitted, performed in a different manner (with other tools, for instance) and/or replaced by other steps; additional steps may be added; and one or more steps can be carried out in a sequence different from the sequence illustrated.

For simplicity and ease of explanation, the following description will refer to processing of a single unit cell of a thermoelectric generator device. It is otherwise understood that a plurality of unit cells (in one or more devices) may be concurrently processed as described herein.

FIG. 3A illustrates a unit cell of a thermoelectric generator device (similar to what is illustrated in FIG. 1) comprising a thermoelectric membrane 100 (the detailed structure of the membrane 100 is not visible for simplicity) formed on a backside layer 14. The supporting layer comprises portions of thermally conductive material 14A (such as silicon, for instance) and empty portions 14B.

The unit cell illustrated in FIG. 3A may be a portion of a wafer/panel comprising a plurality of unit cells intended to be concurrently processed.

FIG. 3B illustrates a protective layer 200 provided on the front/top surface of a unit cell in order to protect the membrane of the unit cell by forming a first encapsulation thereof.

The protective layer 200 may advantageously be provided at wafer/panel level, that is by concurrently processing a plurality of unit cell to provide them with a protective layer 200 as illustrated in FIG. 2.

The protective layer 200 as illustrated in FIG. 3B may advantageously be provided via a method that involves applying relatively low pressure and mechanical stress to the membrane 100 of the cell.

According to an embodiment of the present description, the protective layer 200 may be provided by laminating a mold film on the unit cell. Laminating a mold film (such as an epoxy resin mold film, for instance) may advantageously be made at wafer/panel level.

Commercially available mold films, such as mold film available under the trade designation EB 4010S with Resonac of 13-9, Shiba Daimon 1-Chome, Minato-ku, Tokyo 105-8518, Japan can be used in embodiments of the present description.

According to an embodiment of the present description, the protective layer 200 may be provided via dispensing or via spin coating of an electrically insulating resin such as polyimide (PI), for instance.

As known to those skilled in the art, subsequently to providing such a protective layer 200 via lamination or spin coating, a curing step of the protective layer 200 may be envisaged; this may be via thermal treatment or via exposure to UV light of the protective layer 200.

As further discussed in the following, a protective layer 200 as illustrated in FIG. 3B protects the structured membrane 100 from the mechanical stress and relatively high pressure that develops during a molding step.

Advantageously, a protective layer 200 as illustrated in FIG. 3B may be provided at wafer/panel level, that is, by concurrently providing such an encapsulation to a plurality of unit cells comprised in an array (a panel or a wafer) of such unit cells. This may involve: providing a common supporting layer 14 of thermally conductive material; forming a common structured membrane 100 at a surface of the common supporting layer 14, (where the common structured membrane comprises a plurality of portions comprising an individual structured membranes 100 as illustrated in FIG. 3A, for instance); forming a plurality of cavities 14B at selected regions of the common supporting layer 14; providing (via film lamination or spin coating, for instance) a protective layer 200 at a surface of the common structured membrane 100; and singulating (via sawing with a blade, for instance) the common supporting layer 14 supporting the common structured membrane 100 thus obtaining a plurality of unit cells having a (first) protective layer 200 provided at the top/front surface thereof.

The singulated unit cells are thus arranged on a supporting frame. As mentioned, the supporting frame 12 comprises thermally conductive mounting locations 12A (also referred to as dissipation frame) and a connection frame 12B that is configured to be electrically coupled to the unit cells.

Both the dissipating portions 12A and the connecting portions 12B of the substrate/frame 12 can be made of a same thermally and electrically conductive material (a metal such as copper, for instance).

FIG. 3C is illustrative of a unit cell arranged at a mounting location 12A of a supporting frame 12. As illustrated, the supporting frame 12 may be arranged on a temporary (and possibly sacrificial) carrier S in order to facilitate further processing.

As illustrated in FIG. 3C, a molding step is performed to provide an electrically insulating protective encapsulation to the devices. An electrically insulating molding compound 20 such as an epoxy resin is (pressure) molded on the unit cells arranged on the supporting frame 12. As discussed in the following, the electrically insulating molding compound 20 may be a molding compound suitable for laser direct structuring (LDS).

As mentioned, the protective layer 200 provided on the top/front surface of the structured membranes 100 reduces the mechanical stress applied thereto during the molding step.

The protective layer 200, such as a mold film laminated on the cell or an electrically insulating material (polyimide, PI, for instance) provided at the top/front surface of the membrane 100 has been found to effectively counter breaking of the membrane 100, thus facilitating the manufacturing process of a thermoelectric generator device as described herein.

Advantageously, suitable materials for the protective layer 200 are sufficiently rigid (stiff) to counter breaking of the structured membrane 100 at its portion 1000 above the cavity 14B during a molding step.

In order to effectively counter mechanical stress developed in the membrane 100 in response to the molding step, the protective layer 200 may be provided at a portion of the top/front surface extending beyond (and comprising) the portion 1000 of the membrane 100 above the cavity 14B. In other words, the protective layer 200 provides an encapsulation of the pad 19 formed at the region 1000 of the membrane 100 where the encapsulation contacts the top/front surface of the membrane 100 at a portion thereof surrounding the region 1000. As those skilled in the art may appreciate, a protective layer 200 provided at wafer/panel level (via lamination or spin coating, for instance) may result in a protective layer 200 covering the whole top/front surface of the membrane 100, as illustrated in FIG. 3C.

As mentioned, the protective layer 200 comprise a material that are stiff/rigid enough (at molding condition) to counter breaking of the membrane 100. In general, in addition to the already mentioned materials, it has been found that (electrically insulating) encapsulating materials having a Young modulus (at molding condition) greater than 0.7 GPa, preferably greater than 1.0 GPa, effectively counter breaking of the structured membrane 100 during the molding step.

According to certain embodiments the protective layer 200 may be formed by providing (via lamination or spin coating, for instance) a (thermosetting) resin at the top/front surface of the membrane 100. A molding step as illustrated in FIG. 3C may be performed at a temperature higher than the glass transition temperature of the (cured) resin. Suitable resin materials for the protective layer 200 are thus resins having a Young modulus greater than 0.7 GPa (preferably, greater than 1.0 GPa) at temperature higher than their glass transition temperature. It is observed that for a vast class of such resins, this may correspond to a Young modulus greater than 10 GPa (preferably more than 15 GPa) at temperatures below their glass transition temperature.

The molding step illustrated in FIG. 3C may be considered a second encapsulation step in a multi-step encapsulation process intended to reduce the mechanical stress (and the risk of breaking) of fragile portions of the devices (such as the portion 1000 of the membranes 100 illustrated in the figures) under processing.

FIGS. 3D and 3E illustrate processing steps providing electrically and thermally conductive paths landing on the pads 18 and 19 on the top/front surface of the structured membranes 100.

Similarly to what has been discussed in relation to the pads 18,19, the coupling paths landing thereon may be made of a same electrically and thermally conductive material (a metal such as copper, for instance).

FIG. 3D illustrates (through mold) vias 180′,190′ opened (via laser machining LB, for instance) in the molding compound 20 toward the pads 18, 19 and the portion 12B of the supporting frame 12. Vias 180′ to the pad 18 and the connection frame 12B are indicated with the same reference in the figures since they are configured to form one electrically conductive path from the pad 18 to the connection frame 12B.

As illustrated, vias 180′, 190′ to the pads 18, 19 extend through the protective layer 200 in order to expose the pads 18,19 and thus facilitating subsequent processing.

FIG. 3E illustrates a growth/deposition step where electrically conductive material (a metal such as copper, for instance) is deposited/grown to provide electrically and thermally conductive vias 180, 190 (referenced with no accent any longer, to indicate that proper electrically and thermally conductive vias have been formed) between the pad 19 and the front/top surface of the encapsulation 20 and between the connection frame 12B and the pad 18. As illustrated, the electrical coupling between the connection frame 12B and the pad 18 may comprise an electrically conductive trace 181 extending on the front/top surface of the encapsulation 20.

Vias 180, 190 and traces 181 may be provided via any method known to those skilled in the art.

For example, conventional electrochemical deposition/growth process may be used to form electrically conductive vias 180, 190 and traces 181.

According to an embodiment, vias 180, 190 and traces 181 may be formed via laser direct structuring (LDS).

LDS is a laser-based machining technique that involves transferring (“structuring”) a desired electrically conductive pattern onto an LDS-suitable (that is, with additives suitable for the LDS process embedded therein) plastic molding that may then be subjected to metallization to finalize a desired conductive pattern.

Laser machining of the LDS-suitable molding compound “activates” the additive particles embedded therein thus facilitating subsequent metallization steps.

Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

Reference is made to United States Patent Application Publication Nos. 2018/0342453, 2019/0115287, 2020/0203264, 2020/0321274, 2021/0050226, 2021/0050299, 2021/0183748, or 2021/0305203 as exemplary of the possibility of applying LDS technology in manufacturing semiconductor devices.

In the case electrically conductive vias 180, 190 and traces 181 are provided via LDS, the molding compound is chosen to be an LDS-suitable compound and growing/depositing metallic material to form electrically and thermally conductive vias 181, 191 and traces 182 is done via an electroless plating followed by electrolytic deposition.

FIG. 3F is illustrative of a second layer of encapsulating compound 22 (such as an epoxy resin, for instance, possibly with LDS additives embedded therein) transfer molded on top/front surface of the first encapsulation layer 20.

FIGS. 3G and 3H are illustrative of processing steps providing through mold vias 191 from the top/front surface of the devices (top/front surface of the encapsulation layer 22) to the topmost portion of the via 190 by growing/depositing thermally conductive material (a metal such as copper, for instance).

Processing to form vias 191 may be done as described in relation to FIGS. 3D and 3E for providing vias 180, 190, for instance via electrochemical deposition and/or laser direct structuring; in the latter case the molding compound 22 is an LDS suitable compound, with LDS additive particles embedded therein.

Vias 190, 191 and pad 19 form a thermally conductive path extending through the molding compound 20,22 from the top/front surface of the device to the structured membranes 100.

Vias 180 and traces 181 from an electrically conductive path extending through the molding compound 20,22 from the top/front surface of the structured membrane 100 to the connecting portion 12B of the frame 12.

In summary, processing steps described in relation with FIGS. 3A to 3F comprise providing a thermoelectric unit including a thermoelectric membrane 100 having a first surface at a cavity 14B in a layer of first thermally conductive material 14.

The thermoelectric membrane 100 has a second surface opposite to the first surface with second thermally conductive material 19 arranged in contact with the second surface of the thermoelectric membrane 100.

The thermoelectric membrane 100 includes thermally sensitive material (two differently doped resistors 101, 102, for instance) configured to generate via the Seebeck effect a thermoelectric signal indicative of the temperature difference between the second thermally conductive material 19 and the first thermally conductive material 14.

An insulating molding compound 20, 22 is molded onto the second thermally conductive material 19 arranged in contact with the second surface of the thermoelectric membrane 100. Mechanical stress develops in the thermoelectric membrane 100 in response to said molding of insulating molding compound 20, 22.

An encapsulation 200 (a mold film, for instance) of the second thermally conductive material 19 is provided at the second surface of the thermoelectric membrane 100.

The encapsulation 200 counters mechanical stress developed in the thermoelectric membrane 100 in response to molding of the insulating molding compound 20, 22.

Processing as described in the foregoing lends itself to be performed (advantageously) at wafer/panel level by providing an array of thermoelectric units sharing a common thermoelectric membrane 100. The common thermoelectric membrane (100) has, at each thermoelectric unit in the array, a first surface at a cavity 14B in the layer of first thermally conductive material 14 and a second surface opposite to the first surface with the second thermally conductive material 19 arranged in contact with the second surface of the common thermoelectric membrane 100.

An encapsulation 200 is provided (via film lamination or spin coating, for instance) at the second surface of the common thermoelectric membrane.

The thermoelectric units in said array of thermoelectric units are singulated and a plurality of individual thermoelectric units (having respective encapsulation 200 provided) results from singulation.

The individual units are arranged onto a common support substrate/frame 12, and the insulating molding compound 20, 22 is molded onto the individual units arranged on the common support substrate 12.

Advantageously, the encapsulation 200 provided at the second surface of the thermoelectric membrane 100 comprises encapsulation material having a Young modulus greater than 0.7 GPa (preferably greater than 1.0 GPa) at the molding temperature.

Without prejudice to the underlying principles, the details and embodiments may vary, even significantly, with respect to what has been described by way of example only without departing from the extent of protection.

The claims are an integral part of the technical teaching provided in respect of the embodiments.

The extent of protection is determined by the annexed claims.

1. A method, comprising:
providing a thermoelectric unit including a thermoelectric membrane having a first surface at a cavity in a layer of first thermally conductive material, wherein the thermoelectric membrane has a second surface opposite to the first surface with second thermally conductive material arranged in contact with the second surface of the thermoelectric membrane, wherein the thermoelectric membrane includes thermally sensitive material configured to generate, via a Seebeck effect, a thermoelectric signal indicative of a temperature difference between the second thermally conductive material and the first thermally conductive material;
molding an insulating molding compound onto the second thermally conductive material arranged in contact with the second surface of the thermoelectric membrane wherein said molding develops a mechanical stress in the thermoelectric membrane; and
providing at the second surface of the thermoelectric membrane an encapsulation of the second thermally conductive material arranged in contact with the second surface of the thermoelectric membrane, wherein the encapsulation counters mechanical stress developed in the thermoelectric membrane.

2. The method of claim 1, wherein said molding is done at a molding temperature, and wherein the encapsulation provided at the second surface of the thermoelectric membrane comprises encapsulation material having a Young modulus greater than 0.7 GPa at said molding temperature.

3. The method of claim 1, wherein the encapsulation provided at the second surface of the thermoelectric membrane comprises resin encapsulation material having a Young modulus greater than 0.7 GPa at a temperature higher than a glass transition temperature of the resin encapsulation material.

4. The method of claim 1, wherein the encapsulation provided at the second surface of the thermoelectric membrane comprises resin encapsulation material having a Young modulus greater than 10 GPa at a temperature lower than a glass transition temperature of the resin encapsulation material.

5. The method of claim 1, comprising providing the encapsulation of the second thermally conductive material with the second thermally conductive material arranged between the encapsulation and the second surface of the thermoelectric membrane.

6. The method of claim 1, comprising providing the second thermally conductive material as a thermally conductive pad arranged in contact with the second surface of the thermoelectric membrane at said cavity.

7. The method of claim 6, comprising providing said encapsulation onto said thermally conductive pad as well as onto the second surface of the thermoelectric membrane around said cavity.

8. The method of claim 1, comprising providing said encapsulation by dispensing or spin coating encapsulation material at the second surface of the thermoelectric membrane.

9. The method of claim 1, comprising providing said encapsulation by laminating a mold film of encapsulation material at the second surface of the thermoelectric membrane.

10. The method of claim 1, wherein the insulating molding compound has an outer surface opposite to the second surface of the thermoelectric membrane, and wherein the method comprises providing at least one thermally conductive formation through the insulating molding compound molded onto the second thermally conductive material, wherein said at least one thermally conductive formation provides a thermally conductive path between the outer surface of the insulating molding compound and the second thermally conductive material.

11. The method of claim 10, further comprising providing the at least one thermally conductive formation via deposition of metallic material.

12. The method of claim 11, wherein the insulating molding compound molded onto the second thermally conductive material comprises a laser direct structuring (LDS) molding compound, and the method further comprises providing the at least one thermally conductive formation via laser direct structuring of the LDS molding compound.

13. The method of claim 1, comprising:
providing an array of thermoelectric units sharing a common thermoelectric membrane, wherein the common thermoelectric membrane has, at each thermoelectric unit in the array, a first surface at a cavity in the layer of first thermally conductive material and a second surface opposite to the first surface with said second thermally conductive material arranged in contact with the second surface of the common thermoelectric membrane; and
wherein the method comprises:
providing at the second surface of the common thermoelectric membrane an encapsulation of the second thermally conductive material arranged in contact with the second surface of the common thermoelectric membrane;
performing singulation of the thermoelectric units in said array of thermoelectric units wherein a plurality of individual thermoelectric units results from singulation; and
molding said insulating molding compound onto said individual thermoelectric units resulting from singulation wherein said encapsulation of the second thermally conductive material counters mechanical stress developed in response to said molding of insulating molding compound onto said individual thermoelectric units resulting from singulation.

14. The method of claim 13, comprising:
arranging said individual thermoelectric units resulting from singulation onto a common support substrate; and
molding said insulating molding compound onto said individual thermoelectric units resulting from singulation arranged on said common support substrate.

15. The method of claim 14, wherein the common support substrate comprises thermally conductive portions in heat exchange relationship with the layer of first thermally conductive material.

16. The method of claim 14, wherein the common support substrate comprises electrically conductive portions and the method comprises providing electrical coupling formations coupling said electrically conductive portions in the common support substrate with thermally sensitive material in the thermoelectric membrane configured to generate said thermoelectric signal via the Seebeck effect.

17. The method of claim 16, comprising providing said electrical coupling formations via deposition of metallic material.

18. The method of claim 17, wherein the insulating molding compound molded onto the second thermally conductive material comprises a laser direct structuring (LDS) molding compound, and the method comprises providing said electrical coupling formations via laser direct structuring of the LDS molding compound.

19. A method, comprising:
providing a thermoelectric unit including a thermoelectric membrane including thermally sensitive material configured to generate via a Seebeck effect a thermoelectric signal indicative of a temperature difference between a first thermally conductive material and a second thermally conductive material;
covering the thermoelectric membrane and the first and second thermally conductive materials with an encapsulation layer;
molding a first insulating molding compound over the encapsulation layer;
forming a first through via through the first insulating molding compound and the encapsulation layer to reach the first thermally conductive material;
forming a second through via through the first insulating molding compound and the encapsulation layer to reach the second thermally conductive material;
covering the first insulating molding compound with a second insulating molding compound; and
forming a third through via through the second insulating molding compound to reach the second through via.

20. The method of claim 19, wherein the first and second insulating molding compounds are laser direct structuring (LDS) molding compounds.

21. The method of claim 19, wherein the encapsulation layer comprises resin encapsulation material having a Young modulus greater than 0.7 GPa at a temperature higher than a glass transition temperature of the resin encapsulation material.

22. The method of claim 19, wherein the encapsulation layer comprises resin encapsulation material having a Young modulus greater than 10 GPa at a temperature lower than a glass transition temperature of the resin encapsulation material.

23. The method of claim 19, further comprising:
mounting the thermoelectric unit to a support; and
forming a fourth through via through the first insulating molding compound and the encapsulation layer to reach the support.
